(19) United States
(12) Patent Application Publication
(10) Pub. No.: US 2010/0019820 A1
(43) Pub. Date: Jan. 28, 2010

(54) DIGITAL CONTROL SYSTEM AND METHOD

(76) Inventors: Venkatesh P. Pai, Gilbert, AZ (US); Mohammad Rehman, Chandler, AZ (US); Umesh Jayamohan, Chandler, AZ (US)

Correspondence Address: WILLIAM C. CAHILL, 155 PARK ONE, 2141 E. HIGHLAND AVENUE, PHOENIX, AZ, 85016, US

(21) Appl. No.: 12/439,618

(22) PCT Filed: Jan. 23, 2008
(86) PCT No.: PCT/US08/51822

§ 371 Date: Apr. 3, 2009

Related U.S. Application Data
(60) Provisional application No. 60/886,215, filed on Jan. 23, 2007.

(51) Int. Cl. H03H 11/26

(52) U.S. Cl. 327/290

(57) ABSTRACT

A low power monolithic CMOS device incorporating functions to control power supply transition noise such as in audio circuits and systems. The digital control circuit incorporates MOSFETs that are maintained in an OFF state during normal operation and are turned ON only when system power is turned on or off to thus eliminate the need for bias voltages and maintain minimal quiescent current.

### RELATED APPLICATION

This application is related to and claims priority to a provisional application entitled “SWITCHING ATTENUATION AND AGC CONTROLLER AND METHOD” filed Jan. 23, 2007 and assigned Ser. No. 60/886,215.

### FIELD OF THE INVENTION

This invention relates to attenuation control system and particularly to systems and methods for controlling and limiting the amplitude of an output signal prior to its receipt and utilization by succeeding circuits or systems.

### BACKGROUND OF THE INVENTION

Signal attenuation control systems, particularly those relating to audio systems, have generally been characterized by substantial quiescent current and the use of a variety of analog circuits and systems to accurately provide an output signal or control output signals as representations of the system input audio signals. Such techniques and the use of analog circuits have resulted in significant quiescent current requirements and generally results in an annoying capacitive discharge when the audio systems are turned on. This capacitive discharge is manifested in the form of a large “crack” or “pop” sound emanating from the audio system speakers. This characteristic is particularly annoying when the audio system utilizes headsets for use by individuals. The objections to prior art approaches to attenuation control have substantial disadvantages when applied to systems other than audio systems.

### SUMMARY OF THE INVENTION

The system of the present invention incorporates a low power monolithic CMOS mixed signal device. The device functions to control power supply transition noise in various applications such as audio circuits and systems. The system requires very few external components for its operation and works from low to medium power supply voltages of 2.7 volts to 5.5 volts. As the power supply ramps ON or OFF, the system ensures that the audio inputs to succeeding amplifiers are switched to a convenient low impedance voltage rail. This causes such amplifiers to remain silent as a power supply changes state (from ON to OFF and vice versa). The device also includes a digital control pin which can be used by a control device such as a micro-controller or a micro-processor or any other digital controller to enable the audio mute function. This system provides maximum flexibility for monitoring power supplies and battery control functions in systems without backup batteries.

The system consumes less than 50 μA of supply current while providing more than 36 dB of mute attenuation in audio lines. ESD protection circuitry on the outputs protects the system and devices further up the signal chain.

### BRIEF DESCRIPTION OF THE DRAWINGS

FIG. 1 is a schematic block diagram of a system incorporating the teachings of the present invention.

FIG. 2 is a diagram of waveforms of the supervisor circuit of FIG. 1.

FIG. 3 is a diagram of waveforms of the attenuation controller of FIG. 1.

FIGS. 4 and 5 are diagrams of waveforms of the attenuation and release of signals when output lines of the attenuation controller of FIG. 1 is turned on and off, respectively.

FIG. 6 is a block diagram of a system incorporating the teachings of the present invention showing an application incorporating extended AGC functions.

FIG. 7 is a schematic block diagram useful in describing the mute circuit operation of the system of the present invention.

FIG. 8 is an illustration showing waveforms that may be typical during the operation of the system of FIG. 7.

FIGS. 9 and 10 are enlarged portions of the waveforms of FIG. 8.

FIGS. 11 and 12 are waveforms illustrating the mute enable operation of the system shown in FIG. 7.

FIG. 13 is a block level representation of a silicon chip incorporating the system of the present invention.

FIG. 14 is a block diagram representation of a selected portion of FIG. 13.

FIG. 15 is a block diagram of a portion of the diagram of FIG. 14.

FIG. 16 is a block diagram showing internal circuitry of a portion of FIG. 15.

FIG. 17 is a block diagram showing internal portions of selected features of the diagram of FIG. 13.

FIGS. 18 and 19 are block diagrams of internal portions of the blocks of FIG. 17.

FIG. 20 is an illustration of the internal circuitry of a portion of FIG. 18.

FIG. 21 is an illustration of the circuitry that forms a part of FIG. 17.

### DETAILED DESCRIPTION OF THE INVENTION

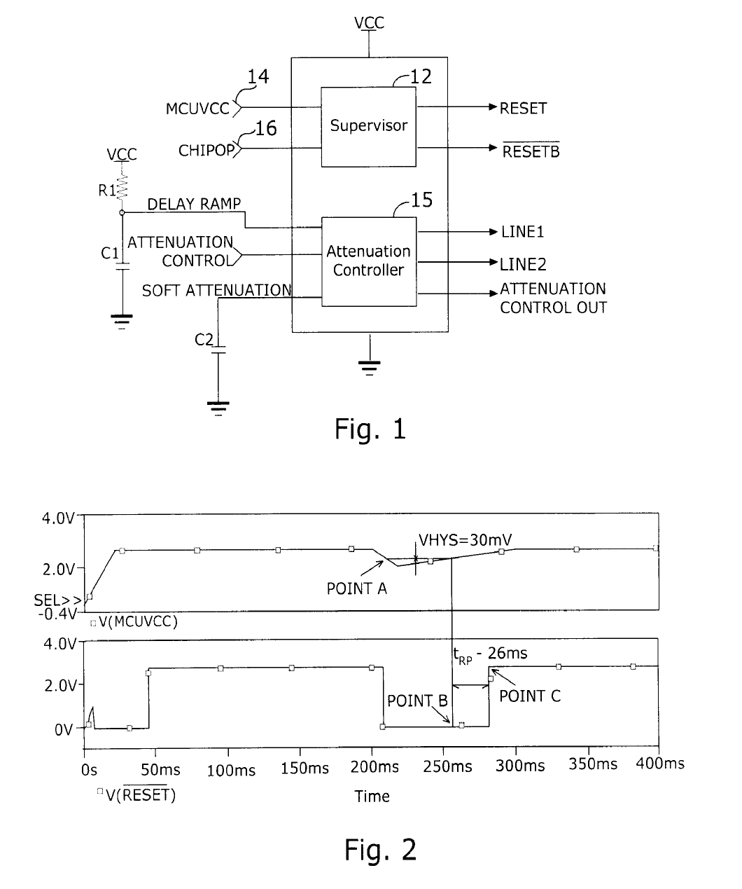

A system incorporating the present invention is shown in FIG. 1 wherein a supervisor circuit 12 constantly monitors the supply voltage to a microprocessor (MCU) at its pin MCUVCC 14. The CHIPOP input 16 is an input to the supervisor that may be set to high voltage for high voltage (5V) operation and to ground for low voltage (<3.3V) operation. When the MCU voltage drops below 90% of maximum value at the MCUVCC pin 14, the supervisor 12 issues a RESET and a RESETB signal. This operation corresponds to Point A in FIG. 2. At this point, another circuit starts operating and delays the signals RESET and RESETB from going to their normal states for a controlled amount of delay time. This delay time is referred to as Reset Time-Out Period and is denoted by t_{RP} in FIG. 2. Internally this reset timeout period t_{RP} is designed to be more than 20 milliseconds. After the delay of t_{RP} is executed, the signals RESET and RESETB are released. In FIG. 2 RESETB signal is shown; the RESET signal has the opposite voltage profile to RESETB and thus is unnecessary to illustrate. The switching or releasing corresponds to Point C in FIG. 2. The attenuation controller 15 (FIG. 1) has three input signals DELAY RAMP, ATTENUATION CONTROL, and SOFT ATTENUATION. These input signals control its operation and three output signals, LINE1, LINE2 and ATTENUATION CONTROL OUT are controlled by the input signals. It has been found that the system should operate most efficiently if the supply voltage ramps to full voltage before any other system changes take place. Typical ramp up-times for chip VCC's could be <20 ms.

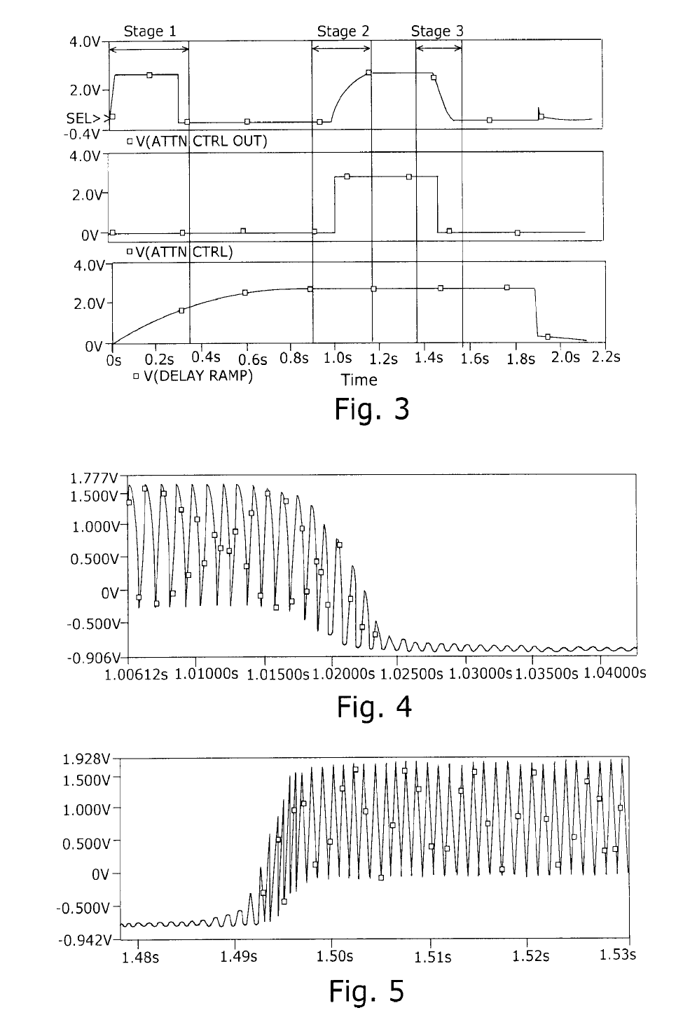

The input signal DELAY RAMP is a delayed ramp input generated by the circuit comprising R1 and C1 as shown in FIG. 1 that provide a slow ramp signal to the controller. As the ramp starts rising, the output lines LINE1 and LINE2 are turned ON until a certain voltage level is reached. When the input voltage is stabilized, the output lines LINE1 and LINE2 are turned OFF. This operation is denoted by stage 1 in FIG. 3. During this stage, the attenuation controller holds the signal lines low so as to prevent unwanted signals to go into the later stages of the system such as an amplifier. This delayed start is deliberately designed into the system to avoid noise from passing through. After the delay ramp has reached a set point, the lines, LINE1 and LINE2, are released. After this point, the attenuation control can be “softly” controlled by using an external capacitor C2 at the SOFT ATTENUATION input. In this instance, when the attenuation control signal is pulled HIGH, the attenuation control signal ramps up slowly, causing the soft attenuation control operation. If a longer ramp time is needed in the attenuation controller, the designer only needs to use a higher value of the capacitor C2. The operation characteristics are shown in FIG. 3. Stage 2 and Stage 3 in FIG. 3 denote the soft attenuation ON and OFF procedures. The ATTENUATION CONTROL OUT signal is an output control that can be used to control additional lines in case an attached system uses more than 2. FIGS. 4 and 5 illustrate signal attenuation operation the moment LINE1 and LINE2 are turned ON and OFF, respectively.

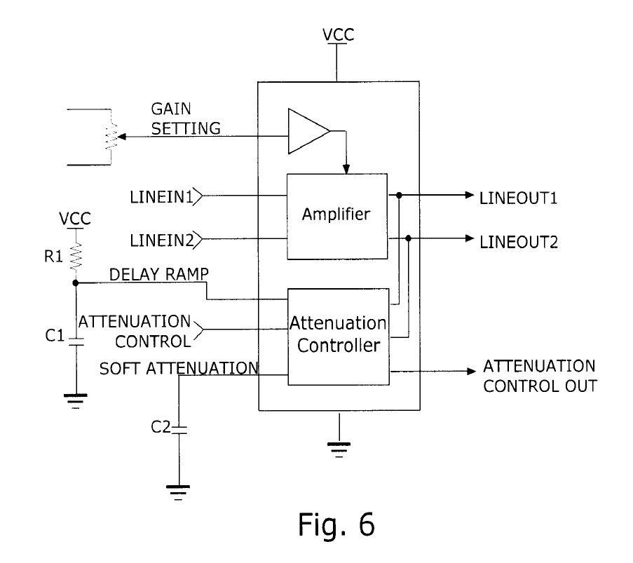

FIG. 6 represents the attenuation controller used in the implementation of an extended AGC system wherein the attenuation controller is tied to an amplifier that receives a GAIN SETTING input. In the application of FIG. 6, two input signals are connected to the amplifier LINEIN1 LINEIN2. The level of these signals is controlled by a GAIN SETTING input that is fed into the amplifier through digital logic. If the signal is above the GAIN SETTING, it is attenuating accordingly so as to maintain a uniform output signal level at LINEOUT1 and LINEOUT2. At the same time, the attenuation controller is monitoring the signal levels at LINEOUT1 and LINEOUT2 and waiting for the attenuation control input signal to be asserted to completely attenuate the signals. There is an ATTENUATION CONTROL OUT signal which can be used to control other signal lines if needed.

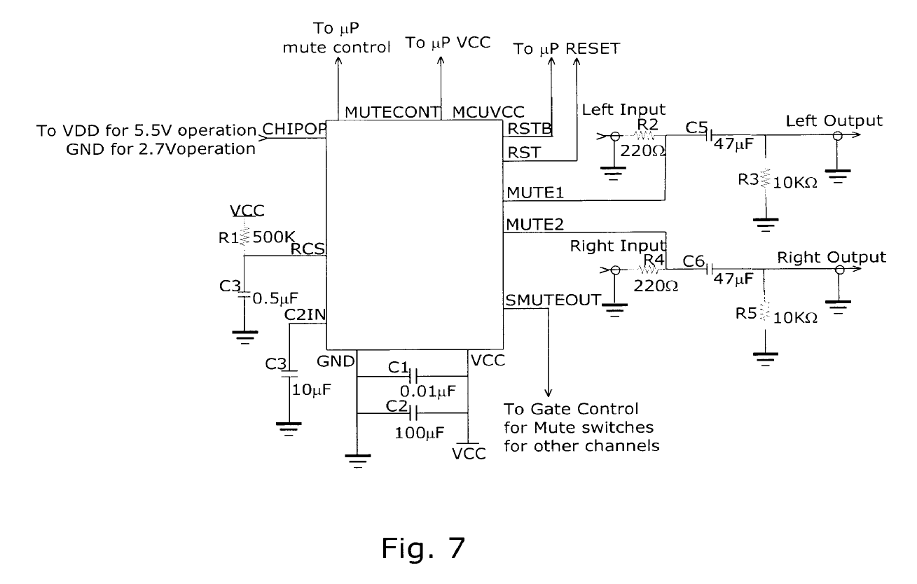

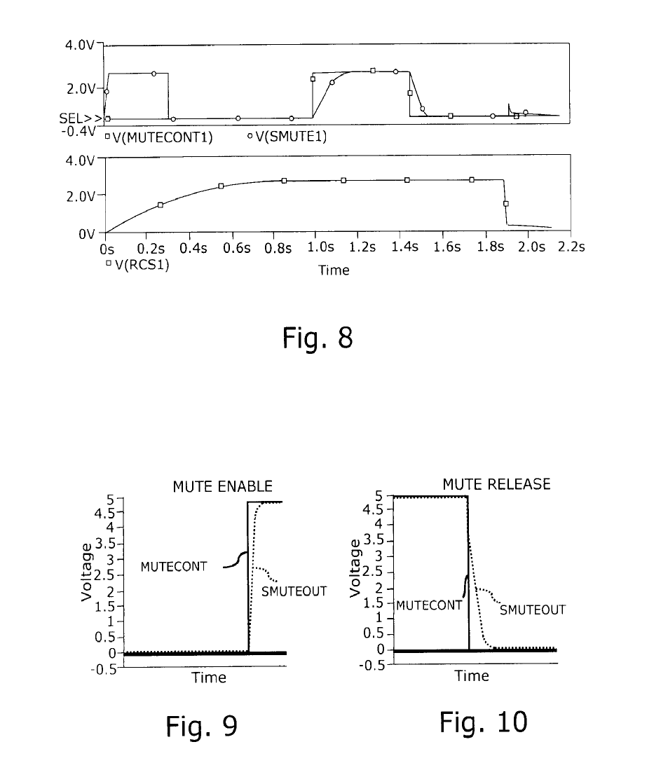

FIG. 7 is an illustration useful in describing the mute circuit operation of the system of the present invention. Caution should be taken to insure that Chip VCC ramps to full voltage before any other change takes place. Typical ramp-up times for Chip VCC could be <20 ms. RCS is a delayed ramp that provides a slow ramp signal to the control circuit as the ramp starts rising, the mute lines are held HIGH until a certain voltage level of RCS is reached. After this point, when the MUTECONT signal is pulled high, the mute control signal ramps up slowly, causing the SOFTMUTE operation. This SOFTMUTE signal can be controlled using an external capacitor connected at CEXT. For the configuration chosen for illustration in FIG. 7, a capacitance of 10 μF has been chosen for connection to CEXT. With this configuration, the ramp time is around 100 ms. If a longer ramp time is needed. the designer only needs to add a higher capacitance value at the pin. The operational characteristics of this mute operation are illustrated in FIGS. 8 through 12. It may be seen that the mute control signal MUTECONT voltage change results in a ramped configuration of the mute signal MUTE1. FIGS. 9 and 10 illustrate this “ramping” in a larger scale. FIGS. 11 and 12 illustrate the turning ON and OFF of the attenuation or mute signal.

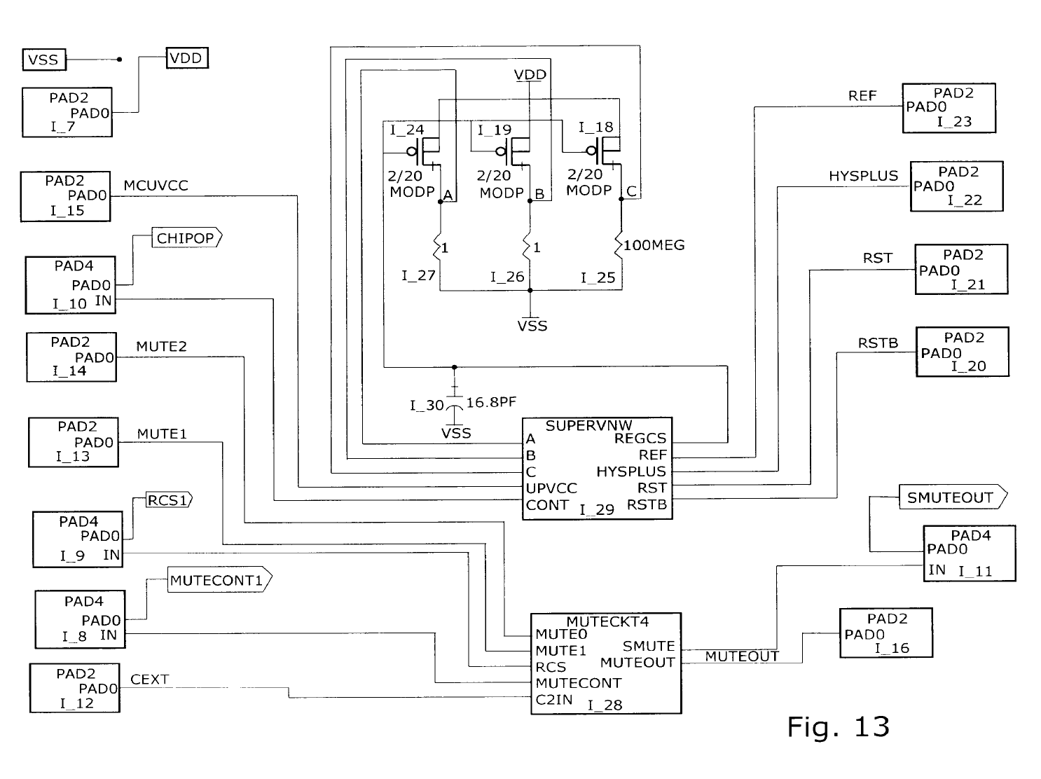

FIG. 13 is a block level representation of the silicon chip used for the system of the present invention. The blocks that are denoted by PAD2 and PAD4 form the connections of the chip to the outside of the package. The chip incorporates two principal components: SUPERVNW and MUTECKT4. The block identified as SUPERVNW, I_29 is a basic microprocessor voltage supervisory circuit. This circuit monitors the power supply given to the microprocessor at block I_15 and sends out a RESET and R̅E̅S̅E̅T̅ signals through blocks I_21 and I_20. The block MUTECKT4, I_28, detects a POWERUP or a POWERDOWN sequence through blocks I_9 and I_7 and sends signals to blocks I_13 and I_14 to tie them to a low voltage (0V or VSS) through a low impedance. In this way the MUTECKT4 block prevents a “pop” noise from being transmitted to the next stages of the system. The MOSFETs represented by I_29 and I_30 are in an OFF state during normal operation and are turned ON only when a POWER-UP or a POWER-DOWN has been detected at the terminal RCS. This and the fact that the complete control circuit is purely digital eliminates the need for bias and voltage reference generators. Therefore, the quiescent current drawn by the current is very small (<1 μA).

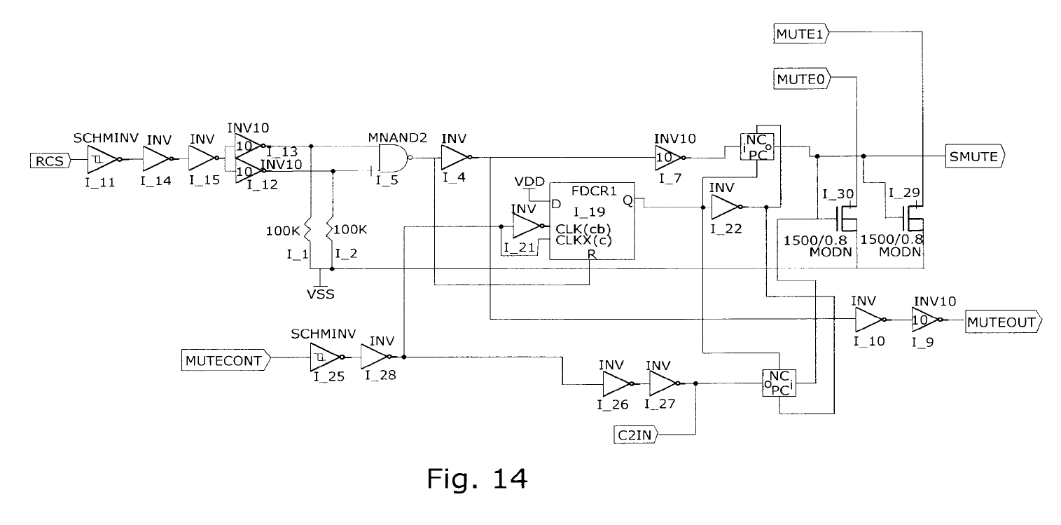

FIG. 14 is a block diagram representing the internal configuration of the MUTECKT4 block described in FIG. 13 above. A resistance is connected between the power source (VCC) and RCS. A capacitance is connected between RCS and ground (VSS). The combination of this resistance and capacitance enables the designer to design any amount of “POWER-UP” delay. This RC connection is illustrated in FIG. 1. A capacitance may be connected to terminal CEXT, although this connection is not required. The connection of such external capacitance to CEXT provides the designer with a control of the ramp time of the SOFTMUTE signal such as shown and described in FIG. 7.

During a POWER-UP sequence, the voltage at RCS will be delayed with respect to the power supply (VDD). This delay voltage lets the output of the digital circuitry formed by devices I_11, I_14, I_15, I_13, I_12 and I_5 to generate RESET signal to the block FDCR1. This sequence will generate a logic HIGH voltage (VCC) to appear at the gates of the MOSFETs I_29 and I_30 through transmission gate (an analog switch) I_20. This will enable the drains of the MOSFETs I_29 and I_30 (terminals MUTE1 and MUTE2) to drop to the low voltage rail (VSS). This process will eliminate the “pop” noise at POWER-UP. After the delayed voltage reaches a certain threshold, the gates of the MOSFETs are pulled back to VSS thus turning them OFF. This is now the normal operation. At this state the whole circuit is in a “dormant” or quiescent state in which the total quiescent current is low.

In this state, if the user asserts a logic HIGH signal at the MUTECONT terminal, circuit resumes its active state in which the gates of the MOSFETs will again be pulled to VCC turning them ON. This will result in the drains of the MOSFETs (terminals MUTE1 and MUTE2) to drop to the low voltage rail (VSS). This results in a mute condition. If an external capacitor is connected to terminal CEXT then the process of muting becomes “soft” dictated by the rate of charging of this external capacitor.

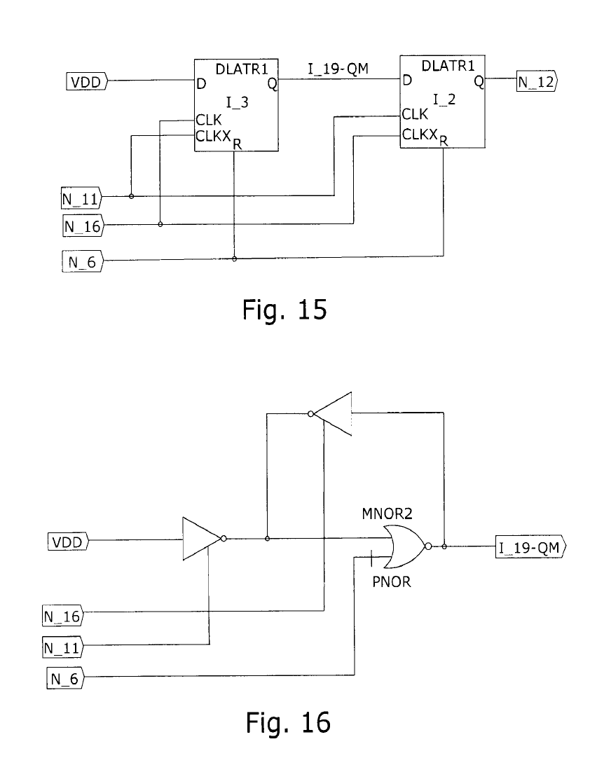

FIG. 15 shows the internals of the block “FDCR1” shown in FIG. 14. This figure illustrates two “D-Latches” working in tandem to generate a control output. The internal circuitry of the DLATR1 blocks used in FIG. 15 are shown in FIG. 16 wherein it may be seen that each D-Latch consists of two “Toggle Inverters” and a NOR gate shown in FIG. 16 as MNOR2.

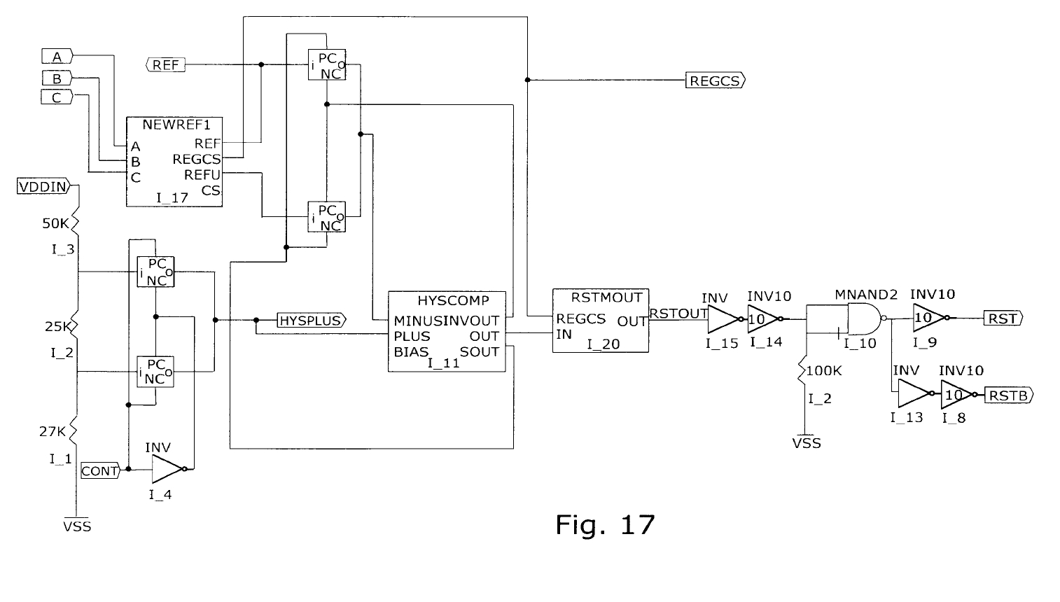

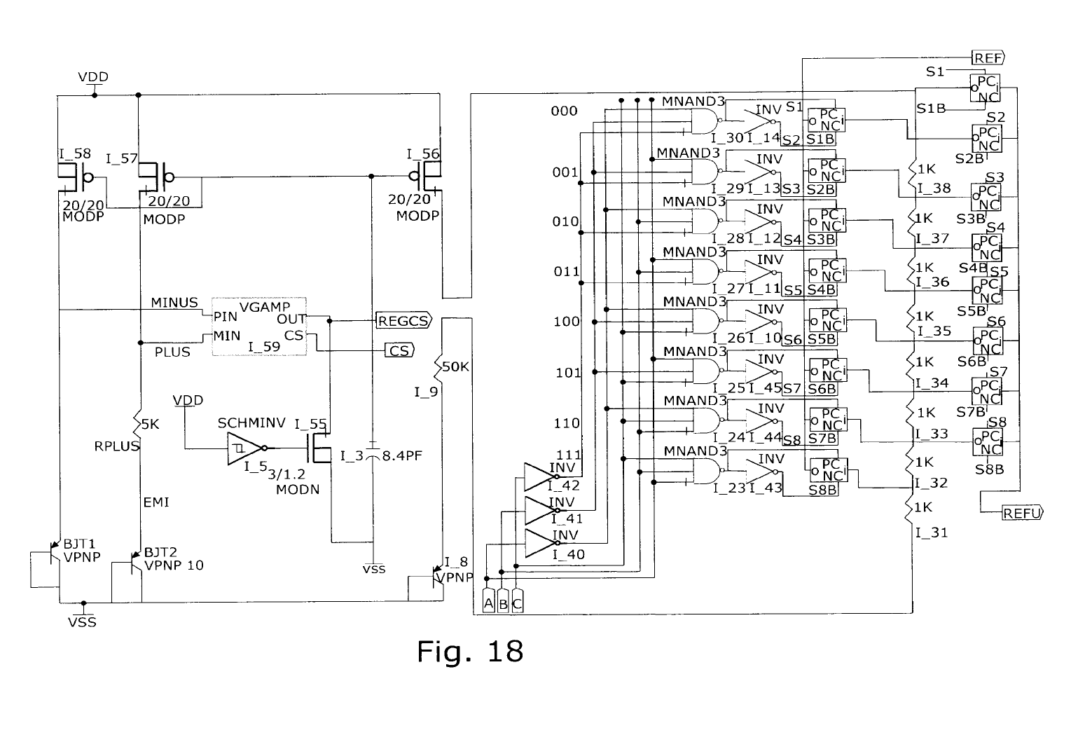

FIG. 17 illustrates the internal configuration of the SUPERVNW block I_29 shown in FIG. 13. It incorporates digital logic and blocks I_17, I_11 and I_20 identified as NEWREF1, HYSCOMP and RSTTMOUT, respectively. The internal configuration of block I_17 shown in FIG. 17 is illustrated in FIG. 18. The block incorporates a bandgap reference generator formed by MOSFET devices I_58, I_57 and I_56, Bipolar transistors BJT1, BJT2 and I_8, and the block VGAMP, I_59. The latter block along with other MOSFET and Bipolar devices generate a stabilized voltage output between instances represented by I_56 (20×20MODP) and I_9 (50k resistor). This voltage is then routed through a resistor divider network. This resistor divider network provides eight voltage taps that can be programmed using the control inputs at terminals “A”, “B” and “C”. These terminals can be found in FIG. 13 by the representations therein of I_24, I_19 and I_18.

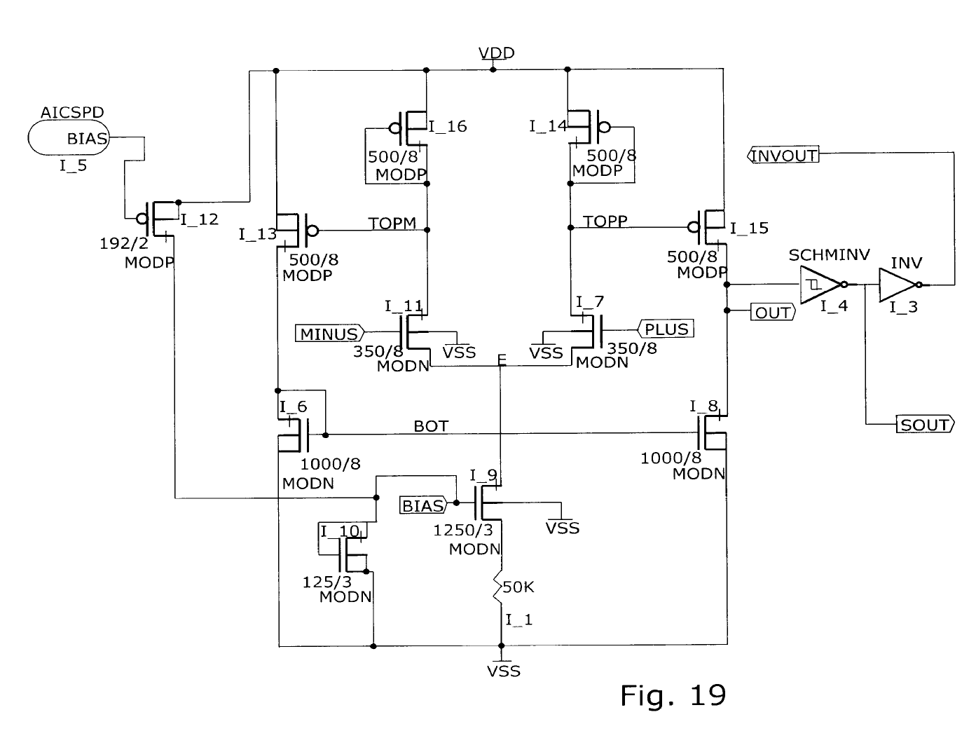

The internal configuration of block I_11 shown in FIG. 17 (HYSCOMP) is shown in FIG. 19. The comparator circuit is an operational amplifier working in open loop with two different voltages being applied to the two input terminals “MINUS” and “PLUS”. The MINUS terminal is connected to the reference voltage generated by block I_17 shown in FIG. 17. The PLUS terminal is connected to a tap that is connected to the power supply voltage being monitored. When the voltage at PLUS is less than the voltage at MINUS the comparator output goes to VCC (upper rail of the power supply). When the voltage at PLUS is less than that at MINUS the comparator output goes to VSS (lower rail of the power supply). The output of the comparator is connected to block I_20 (RSTTMOUT) shown in FIG. 17.

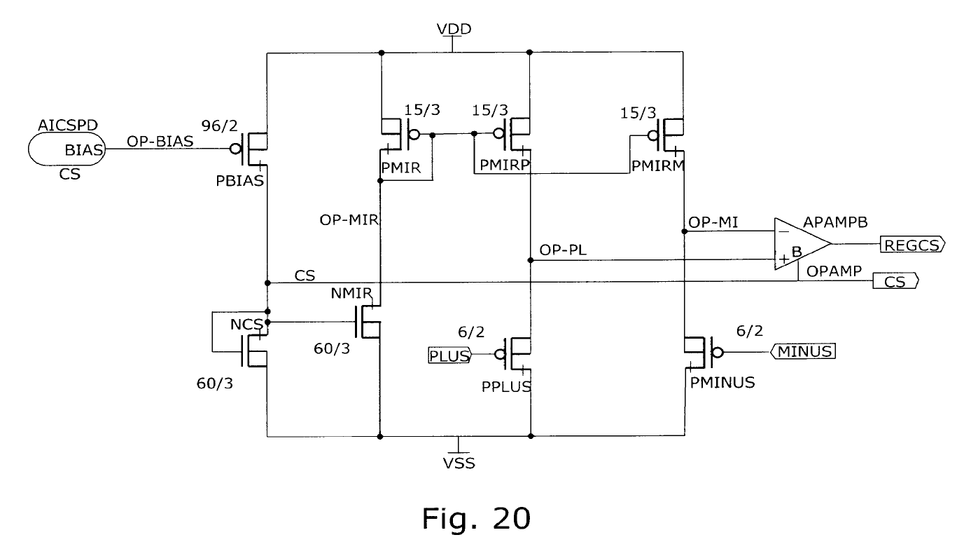

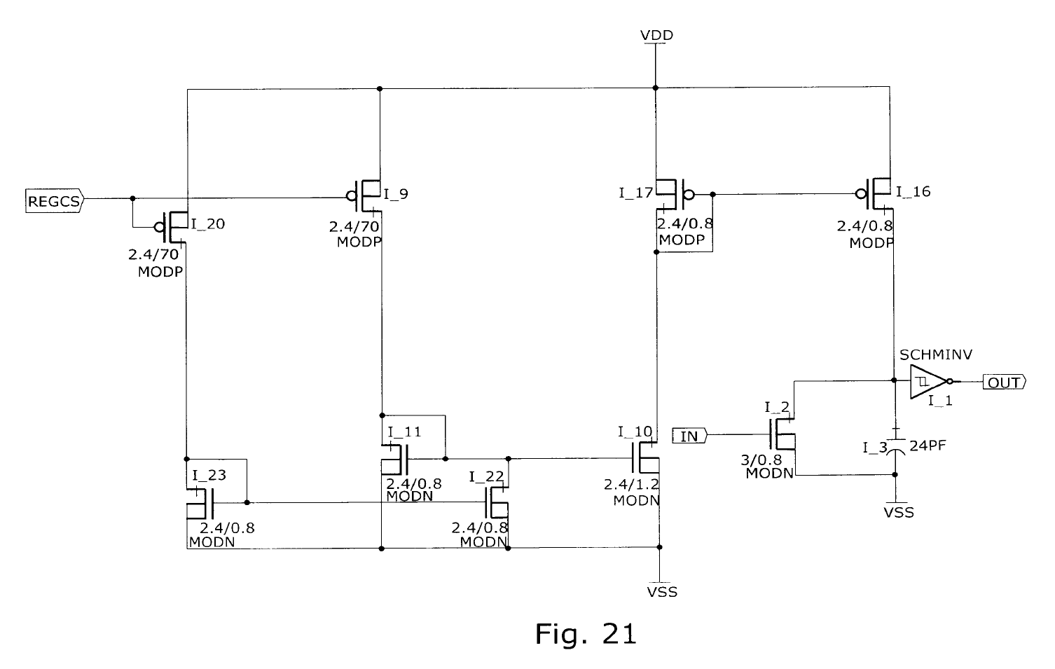

FIG. 20 illustrates the internal circuitry of the block VGAMP (block I_59 shown in FIG. 18). This circuitry incorporates a bias voltage generator block AICSPD and the operational amplifier APAMPB. This difference in voltage applied to the terminals PLUS and MINUS is amplified and then regulated through APAMPB to the output terminal REGCS. This regulated voltage can then be provided through other conditioning circuitry to generate the voltages at terminals REF and REFU shown in FIG. 18.

This is the circuitry that forms the RSTTMOUT (block 1-20 shown in FIG. 17. It consists of two inputs: REGCS is the regulated voltage generated from the circuitry shown in FIG. 18—this is fixed and is supplied to some current generators; and IN is the input signal to the RSTTMOUT block—this signal is the output of the HYSCOMP block (I_11 shown in FIG. 17). When the comparator output voltage is HIGH, the MOSFET I_2 turns on thus discharging the capacitor I_3. The input of the Schmitt inverter I_1 goes low thereby providing an output of VDD (upper rail of the power supply). When the comparator output voltage is LOW, the MOSFET I_2 turns off. The capacitor I_3 starts charging through the current provided by MOSFET I_16. Since the charging time is longer than the discharging time of this capacitor, the output of the Schmitt inverter (terminal OUT) goes to VSS (lower rail of the power supply) only after a delay. This delay causes a REST TIME OUT time delay. Hence, from a system point of view, the RESET signal goes high as soon as the low voltage is detected, but it only goes low AFTER a certain amount of time (dictated by the current through MOSFET I_16) has passed since the voltage has reached its normal high value.

What is claimed:

1. In an attenuation control system for connection to a power supply, the improvement comprising:
(a) means responsive to the application of the power supply voltage for generating a delay ramp signal; and
(b) digital circuit means connected to said delay ramp signal for generating a mute signal when said delay ramp signal is below a predetermined threshold value.

2. The combination of claim 1 wherein said means responsive to the application of the power supply voltage is a series RC circuit, the resistor connected to said power supply, the capacitor connected to ground and the junction of the resistor and the capacitor connected to a control system input to provide a delay ramp signal.

3. The attenuation control system of claims I or 2 wherein said digital circuit means includes at least one MOSFET having a base connected to receive a gating signal and a drain for presenting a mute signal in response to said gating signal.

4. In an attenuation control system for connection to a power supply, the improvement comprising:
(a) a series RC circuit, the resistor connected to said power supply, the capacitor connected to ground and the junction of the resistor and the capacitor connected to a control system input to provide a delay ramp signal; and
(b) digital circuit means having a quiescent state and an active state connected to said delay ramp signal for assuming an active state and generating a mute signal when said delay ramp signal is below a predetermined threshold value, and assuming a quiescent state when said delay ramp signal is above said threshold value.

5. A method for attenuating a power supply voltage comprising:
(a) applying said power supply voltage to the resistor of a series RC circuit, connecting the capacitor to ground to provide a delay ramp signal at the junction of the resistor and capacitor; and
(b) generating a mute signal when said delay ramp signal is below a predetermined threshold level.

6. The method of claim 5 including the step of removing said mute signal when said delay ramp signal is above said predetermined threshold level.
